(19) United States
(12) Patent Application Publication
(10) Pub. No.: US 2025/0259916 A1
(43) Pub. Date: Aug. 14, 2025

(54) PACKAGE STRUCTURE

(71) Applicant: Advanced Semiconductor Engineering, Inc., Kaohsiung (TW)

(72) Inventors: Sheng-Hsiang HSU, Kaohsiung (TW); Cheng-Hung KO, Kaohsiung (TW); I-Jen CHEN, Kaohsiung (TW); Shu-Ting KUO, Kaohsiung (TW)

(73) Assignee: Advanced Semiconductor Engineering, Inc., Kaohsiung (TW)

(21) Appl. No.: 18/437,168

(22) Filed: Feb. 8, 2024

(51) Int. Cl. H01L 23/495; H01L 23/00; H01L 25/065

(52) U.S. Cl. CPC H01L 23/4951; H01L 23/4952; H01L 24/16; H01L 24/48; H01L 25/0657; H01L 2224/16146; H01L 2224/16175; H01L 2224/4801; H01L 2224/48145; H01L 2225/0651; H01L 2225/06517; H01L 2924/01029; H01L 2924/182

(57) ABSTRACT

A package structure includes a lead frame, an electronic device and a level-maintaining structure. The electronic device is disposed adjacent to the lead frame. The level-maintaining structure is disposed between the electronic device and the lead frame, and is configured to prevent the electronic device from tilting with respect to the lead frame. The electronic device includes at least one via protruding from a bottom surface of the electronic device.

### BACKGROUND

### 1. Field of the Disclosure

The present disclosure relates to a package structure, and to a package structure including a carrier.

### 2. Description of the Related Art

In a semiconductor package structure, a noise current may be generated during the operation of the semiconductor package structure. When the distribution of the circuit layers of the semiconductor package structure become denser, the undesired noise current becomes greater, which may adversely affect the performance of the semiconductor package structure. Thus, the elimination or reduction of the current noise is a critical issue.

### SUMMARY

In some embodiments, a package structure includes a lead frame, an electronic device and a level-maintaining structure. The electronic device is disposed adjacent to the lead frame. The level-maintaining structure is disposed between the electronic device and the lead frame, and is configured to prevent the electronic device from tilting with respect to the lead frame. The electronic device includes at least one via protruding from a bottom surface of the electronic device.

In some embodiments, a package structure includes a terminal, an upper pad and a first solder. The upper pad is adjacent to a top surface of the terminal. The first solder is disposed over the upper pad, and is free from contacting a lateral surface of the upper pad. The upper pad is configured to prevent the first solder from lateral bleeding.

In some embodiments, a package structure includes a center region, a periphery region and an intermediate region therebetween from a top view. The package structure further includes an electronic device, a redistribution structure, a carrier, at least one first pad and at least one second pad. The electronic device is disposed in the center region and the intermediate region. The redistribution structure is disposed under the electronic device. The carrier is disposed under the redistribution structure. The at least one first pad is disposed at a contact area between the redistribution structure and the carrier and in the center region. The at least one second pad is disposed at the contact area between the redistribution structure and the carrier and in the intermediate region. A width of the at least one first pad is different from a width of the at least one second pad. The at least one first pad is configured to transmit noise current, and the at least one second pad is configured to transmit signals.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a package structure according to some embodiments of the present disclosure.

FIG. 2 illustrates a partially enlarged view of a region “A” in FIG. 1.

FIG. 2A illustrates a cross-sectional view of a package structure according to some embodiments of the present disclosure.

FIG. 3 illustrates a cross-sectional view of a package structure according to some embodiments of the present disclosure.

FIG. 4 illustrates a cross-sectional view of a package structure according to some embodiments of the present disclosure.

FIG. 5 illustrates a partially enlarged view of a region “B” in FIG. 4.

FIG. 5A illustrates a partially enlarged view of a region of a package structure according to some embodiments of the present disclosure.

FIG. 5B illustrates a cross-sectional view of a package structure according to some embodiments of the present disclosure.

FIG. 5C illustrates a partially enlarged view of a region “B′” in FIG. 5B.

FIG. 6 illustrates a top view of the package structure of FIG. 4.

FIG. 7 illustrates a partially enlarged view of a region “C” in FIG. 6.

FIG. 8 illustrates a cross-sectional view of a package structure according to some embodiments of the present disclosure.

FIG. 9 illustrates a top view of the package structure of FIG. 8.

FIG. 10 illustrates a cross-sectional view of a package structure according to some embodiments of the present disclosure.

FIG. 11 illustrates a partially enlarged view of a region “D” in FIG. 10.

FIG. 12 illustrates a cross-sectional view of a package structure according to some embodiments of the present disclosure.

FIG. 13 illustrates a partially enlarged view of a region “E” in FIG. 12.

FIG. 14 illustrates a cross-sectional view of a package structure according to some embodiments of the present disclosure.

FIG. 15 illustrates one or more stages of an example of a method for manufacturing a package structure according to some embodiments of the present disclosure.

FIG. 16 illustrates one or more stages of an example of a method for manufacturing a package structure according to some embodiments of the present disclosure.

FIG. 17 illustrates one or more stages of an example of a method for manufacturing a package structure according to some embodiments of the present disclosure.

FIG. 18 illustrates one or more stages of an example of a method for manufacturing a package structure according to some embodiments of the present disclosure.

FIG. 19 illustrates one or more stages of an example of a method for manufacturing a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

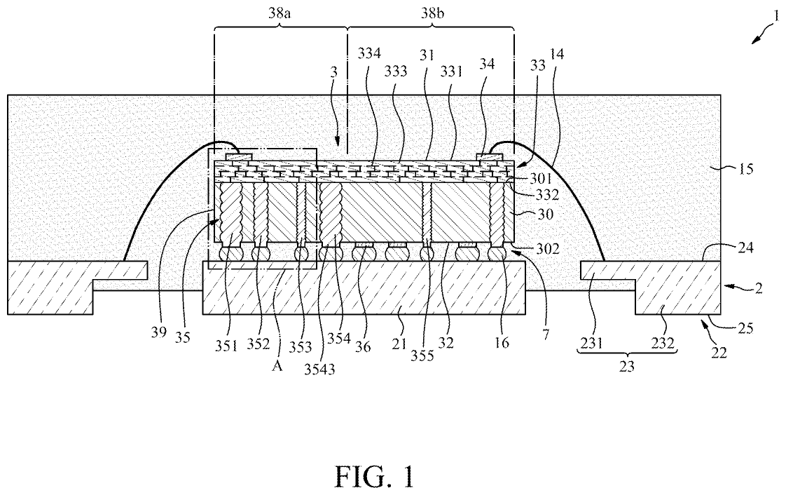

FIG. 1 illustrates a cross-sectional view of a package structure 1 according to some embodiments of the present disclosure. The package structure 1 may be an electronic package structure or a semiconductor package structure. The package structure 1 may include a carrier 2, an electronic device 3, a level-maintaining structure 7, a plurality of conductive wires 14 and an encapsulant 15.

The carrier 2 may be or may include a lead frame, and may include a first portion 21 and a second portion 22 electrically insulated from the first portion 21. The carrier 2 may include a metal material such as copper. The carrier 2 may have a top surface 24 and a bottom surface 25 opposite to the top surface 24. The second portion 22 may be separated from or spaced apart from the first portion 21. The second portion 22 and the first portion 21 may be formed concurrently after an etching process. The first portion 21 may be or may include a ground pad. Thus, the first portion 21 may be used for electrically grounding. Thus, the first portion 21 may be a portion of a grounding path. The grounding path may pass through or extend through the first portion 21, and may not pass through or extend through the second portion 22.

In addition, the second portion 22 may include a plurality of leads 23 disposed around the first portion 21. Each of the leads 23 may be a signal pad. Thus, the second portion 22 (e.g., the leads 23) may be used for transmitting signals. Thus, the second portion 22 (e.g., the leads 23) may be a portion of a signal transmission path. The signal transmission path may pass through or extend through the second portion 22 (e.g., the leads 23), and may not pass through or extend through the first portion 21. In some embodiments, each of the leads 23 of the second portion 22 may include a thinner portion 231 and a thicker portion 232. The thinner portion 231 and the thicker portion 232 may be formed concurrently and integrally. A thickness of the thinner portion 231 may be less than a thickness of the thicker portion 232. The thickness of the thicker portion 232 may be substantially equal to a thickness of the first portion 21. The thinner portion 231 may extend from the thicker portion 232 toward the first portion 21.

The electronic device 3 may be a semiconductor chip or a semiconductor die. The electronic device 3 may be disposed over the first portion 21 of the carrier 2. The electronic device may be disposed adjacent to the carrier 2 (i.e., the lead frame). The electronic device 3 may be disposed on the first portion 21 of the carrier 2, and a projection of the electronic device 3 may be within the first portion 21 of the carrier 2. The electronic device 3 may have a first surface 31 (e.g., a top surface or an active surface), a second surface 32 (e.g., a bottom surface or a backside surface) and a lateral surface 39. The second surface 32 (e.g., a bottom surface or a backside surface) is opposite to the first surface 31 (e.g., the top surface or the active surface). The lateral surface 39 extends between the first surface 31 and the second surface 32. The electronic device 3 may include a main body 30, an active circuit structure 33, a plurality of wire-bonding pads 34 and a plurality of vias 35. The main body 30 may include a semiconductor material such as silicon, and may have a first surface 301 (e.g., a top surface) and a second surface 302 (e.g., a bottom surface) opposite to the first surface 301 (e.g., the top surface).

The active circuit structure 33 may be disposed adjacent to the first surface 31 (e.g., the top surface or the active surface) of the electronic device 3. The active circuit structure 33 may be disposed on the first surface 301 (e.g., the top surface) of the main body 30, and may have a first surface 331 (e.g., a top surface) and a second surface 332 (e.g., a bottom surface) opposite to the first surface 331 (e.g., the top surface). Thus, the second surface 332 (e.g., the bottom surface) of the active circuit structure 33 may contact the first surface 301 (e.g., the top surface) of the main body 30. Further, the active circuit structure 33 may include a dielectric structure 333 and a plurality of circuit layers 334 embedded in the dielectric structure 333. For example, the dielectric structure 333 may include a plurality of dielectric layers stacked on one another. The circuit layers 334 may be or may include a front-end-of-line (FEOL), a middle-of-line (MOL) and/or a back-end-of-line (BEOL).

The vias 35 may be disposed in the main body 30, may extend through the main body 30. Thus, the vias 35 may extend from the first surface 301 (e.g., the top surface) of the main body 30 to the second surface 302 (e.g., the bottom surface) of the main body 30, and may be also referred to as “through silicon vias (TSVs)”. The top ends of the vias 35 may be exposed by the first surface 301 (e.g., the top surface) of the main body 30. The circuit layers 334 of the active circuit structure 33 may be electrically connected to the top ends of the vias 35. The bottom ends of the vias 35 may be exposed by the second surface 302 (e.g., the bottom surface) of the main body 30. The vias 35 may include a conductive metal such as copper. The vias 35 may have inconsistent gaps between adjacent vias 35 and may be configured to transmit noise current.

In some embodiments, the vias 35 may include a first via 351, a second via 352, a third via 353, a fourth via 354 and a fifth via 355. The first via 351, the second via 352 and the third via 353 may be conductive vias that have a function of electrical conduction. The fourth via 354 and the fifth via 355 may be dummy vias that do not have the function of electrical conduction.

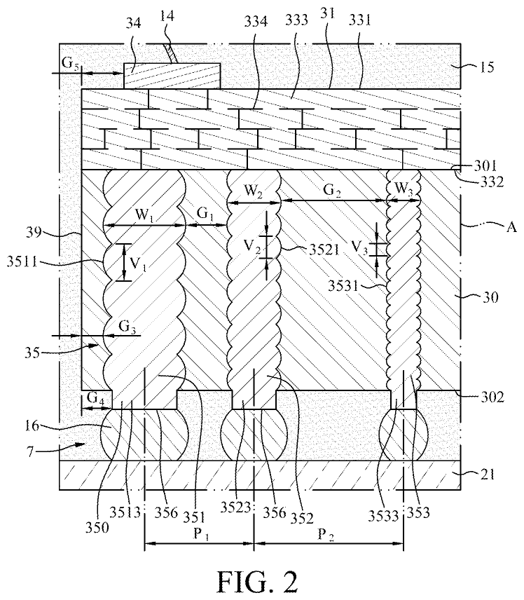

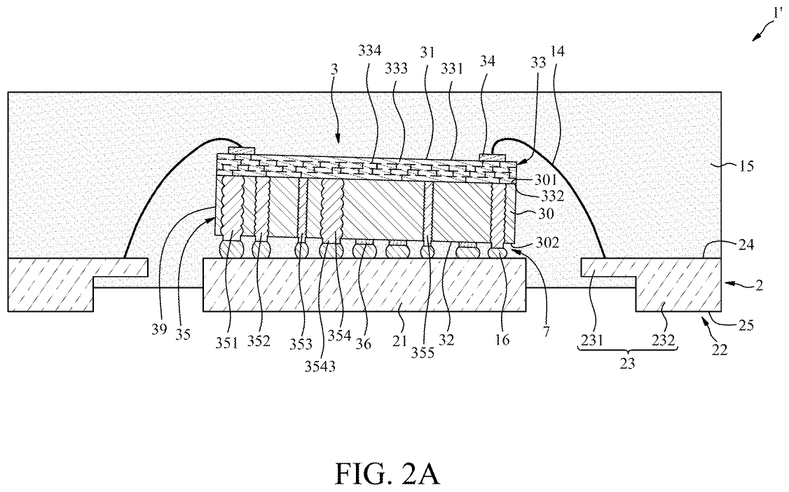

In some embodiments, the first surface 331 (e.g., the top surface) of the active circuit structure 33 may be the first surface 31 (e.g., the top surface or the active surface) of the electronic device 3. The second surface 302 (e.g., the bottom surface) of the main body 30 may be the second surface 32 (e.g., the bottom surface or the backside surface) of the electronic device 3. The vias 35 may protrude from or extend beyond the second surface 32 (e.g., the bottom surface or the backside surface) of the electronic device 3. The vias 35 may include a plurality of protrusion portions 350 (FIG. 2) protruding from the second surface 32 (e.g., the bottom surface or the backside surface) of the electronic device 3. For example, the dummy via 354 may include a protrusion portion 3543 protruding from the second surface 32 (e.g., the bottom surface or the backside surface) of the electronic device 3.

The electronic device 3 may further includes a high-density region 38a and a low-density region 38b. A distribution density of the vias 35 in the high-density region 38a is greater than a distribution density of the vias 35a in the low-density region 38b. That is, the count of the vias 35 in a unit area of the high-density region 38a is greater than the count of the vias 35 in an equal unit area of the low-density region 38b. The level-maintaining structure 7 may be disposed under the low-density region 38b. The level-maintaining structure 7 may be further disposed under the high-density region 38a.

The level-maintaining structure 7 may be disposed between the main body 30 of the electronic device 3 and the first portion 21 of the carrier 2, and may electrically connect the main body 30 of the electronic device 3 and the first portion 21 of the carrier 2. The level-maintaining structure 7 may be disposed under the electronic device 3. The top ends of the vias 35 may be electrically connected to the circuit layers 334 of the active circuit structure 33. The bottom ends of the vias 35 may be electrically connected to the level-maintaining structure 7. Thus, the vias 35 may be electrically connected to the first portion 21 of the carrier 2 through the level-maintaining structure 7. The level-maintaining structure 7 may be configured to maintain or keep a level of the first surface 31 (e.g., the top surface or the active surface) of the electronic device 3. That is, the level-maintaining structure 7 may be configured to prevent the electronic device 3 from tilting with respect to the carrier 2 before and after a wire-bonding process. The level-maintaining structure 7 may include a conductive material such as metal. Thus, the level-maintaining structure 7 may be not only a bonding layer, or an adhesive layer.

In some embodiments, the level-maintaining structure 7 may be configured to maintain a level of a wire-bonding pad 34 disposed adjacent to the first surface 31 (e.g., the top surface or the active surface) of the electronic device 3. The level-maintaining structure 7 may be configured to keep the wire-bonding pad 34 on the top surface 31 of the electronic device 3 at a substantially same elevation. The level-maintaining structure 7 may be configured to maintain at least two of the wire-bonding pads 34 disposed adjacent to the top surface 31 of the electronic device 3 at a substantially same level.

The level-maintaining structure 7 may include a plurality of protrusion portions 350 of the vias 35, a plurality of dummy pads 36 and a plurality of reflowable materials 16. For example, the level-maintaining structure 7 may include the protrusion portion 3543 of the dummy via 354. The dummy pads 36 (or bumps or posts) may be disposed adjacent to or disposed on the second surface 302 (e.g., the bottom surface) of the main body 30 (e.g., the second surface 32 (e.g., the bottom surface or the backside surface) of the electronic device 3). The dummy pads 36 may include a metal material such as copper, aluminum or gold. Further, the dummy pads 36 may protrude from the second surface 302 (e.g., the bottom surface) of the main body 30 (e.g., the second surface 32 of the electronic device 3). The reflowable materials 16 (e.g., solder materials) may include a metal material such as a tin-silver (SnAg) alloy, a tin-copper (SnCu) alloy, or a gold-tin (AuSn) alloy.

The reflowable materials 16 may connect the dummy pads 36 to the first portion 21 of the carrier 2. In some embodiments, the dummy pads 36 may be a portion of the electronic device 3. There may be no via 35 that connects to the dummy pad 36. Thus, the dummy pad 36 does not have electrical function. There may be no electrical current that flows through or passes through the dummy pad 36. The dummy pad 36 may be disposed between the reflowable material 16 and the electronic device 3, and configured to adjust a thickness of the reflowable material 16.

In some embodiments, the level-maintaining structure 7 (including the reflowable materials 16 and the dummy pads 36) may be substantially evenly distributed in the space between the main body 30 of the electronic device 3 and the first portion 21 of the carrier 2. In a reflow process, the reflowable materials 16 may be melted, and the second surface 302 (e.g., the bottom surface) of the main body 30 may remain horizontal with respect to a top surface of the first portion 21 of the carrier 2. After the reflow process, the reflowable materials 16 may be solidified, thus, the gap between the second surface 302 (e.g., the bottom surface) of the main body 30 and the top surface 24 of the first portion 21 of the carrier 2 may be fixed and consistent. As a result, the level-maintaining structure 7 may maintain or keep the level of the first surface 31 (e.g., the top surface or the active surface) of the electronic device 3. The level-maintaining structure 7 may be configured to ensure that the entire first surface 31 (e.g., the top surface or the active surface) of the electronic device 3 is at a same elevation. The first surface 31 (e.g., the top surface or the active surface) of the electronic device 3 may be substantially parallel with the top surface 24 of the carrier 2, so as to facilitate the wire-bonding process.

The wire-bonding pads 34 may be disposed adjacent to the first surface 31 (e.g., the top surface or the active surface) of the electronic device 3. The wire-bonding pads 34 may include a metal material such as copper, aluminum or gold. For example, the wire-bonding pads 34 may be disposed on the first surface 331 (e.g., the top surface) of the active circuit structure 33, so as to electrically connect to the vias 35 through the active circuit structure 33. One of the wire-bonding pads 34 may vertically overlap one of the vias 35. That is, one of the vias 35 may be disposed under one of the wire-bonding pads 34. There may be one or two vias 35 that are electrically connected to one wire-bonding pad 34.

The conductive wires 14 may electrically connect the electronic device 3 and the second portion 22 of the carrier 2. For example, each of the conductive wires 14 may electrically connect the wire-bonding pad 34 of the electronic device 3 and the thinner portion 231 of the lead 23 of the second portion 22 of the carrier 2. The conductive wires 14 may be electrically connected to the active circuit structure 33. One end of the conductive wire 14 may physically connect to the wire-bonding pad 34 of the electronic device 3, and the other end of the conductive wire 14 may physically connect to the thinner portion 231 of the lead 23 of the second portion 22 of the carrier 2. Due to the solid support of the level-maintaining structure 7 (including the reflowable materials 16 and the dummy pads 36), the electronic device 3 may not tilt after the wire-bonding process.

As shown in FIG. 1, the active circuit structure 33 of the electronic device 3 may be electrically connected to the first portion 21 (e.g., a ground pad) of the carrier 2 through the vias 35 and the level-maintaining structure 7 (including the reflowable materials 16 and the dummy pads 36), so as to transmit noise current. In addition, the active circuit structure 33 of the electronic device 3 may be electrically connected to the second portion 22 of the carrier 2 through the conductive wires 14, so as to transmit signals. Thus, the noise current in the active circuit structure 33 of the electronic device 3 may flow to the first portion 21 (e.g., a ground pad) of the carrier 2 through the vias 35 and the level-maintaining structure 7 (including the reflowable materials 16 and the dummy pads 36). In addition, the signals of the active circuit structure 33 of the electronic device 3 may be transmitted to the second portion 22 of the carrier 2 through the conductive wires 14. Therefore, the noise current of the package structure 1 may be eliminated or reduced, and the performance of the package structure 1 may be improved.

The encapsulant 15 (e.g., a molding compound with or without fillers) may encapsulate the electronic device 3, the level-maintaining structure 7 and a portion of the carrier 2. For example, the encapsulant 15 may encapsulate and cover the electronic device 3, the level-maintaining structure 7, the conductive wires 14 and an upper portion of the carrier 2 (including an upper portion of the first portion 21 and an upper portion of the second portion 22). Thus, a lower portion of the first portion 21 and a lower portion of the second portion 22 may be exposed by the encapsulant 15 for external connection. A portion of the encapsulant 15 may extend into a gap between the first portion 21 of the carrier 2 and the second portion 22 of the carrier 2.

FIG. 2 illustrates a partially enlarged view of a region “A” in FIG. 1. The vias 35 may have different widths. The first via 351 is an outermost via. The first via 351 is closer to the lateral surface 39 of the electronic device 3 than the second via 352 is. In some embodiments, the first via 351 may have a first width W₁. The second via 352 may have a second width W₂. The third via 353 may have a third width W₃. The first width W₁ of the first via 351 may be greater than the second width W₂ of the second via 352. The second width W₂ of the second via 352 may be greater than the third width W₃ of the third via 353. The first width W₁, the second width W₂ and the third width W₃ may be different from each other.

The first via 351 may include a protrusion portion 3513 protruding from the second surface 32 of the electronic device 3, and may have a bottom surface 356. The second via 352 may include a protrusion portion 3523 protruding from the second surface 32 of the electronic device 3, and may have a bottom surface 356. The third via 353 may include a protrusion portion 3533 protruding from the second surface 32 of the electronic device 3, and may have a bottom surface 356. The level-maintaining structure 7 may further include the protrusion portions 350 of the vias 35 (e.g., the protrusion portion 3513 of the first via 351, the protrusion portion 3523 of the second via 352 and the protrusion portion 3533 of the third via 353). The bottom surfaces 356 of the vias 35 (e.g., the first via 351, the second via 352 and the third via 353) may be substantially level or aligned with each other.

In addition, a pitch of the vias 35 may be inconsistent. In some embodiments, a first pitch P₁ may be a distance between a center of the first via 351 and a center of the second via 352. A second pitch P₂ may be a distance between the center of the second via 352 and a center of the third via 353. The first pitch P₁ may be different from the second pitch P₂. For example, the first pitch P₁ may be less than the second pitch P₂. Further, a gap of the vias 35 may be inconsistent. In some embodiments, a first gap G₁ may be a spacing between the first via 351 and the second via 352. A second gap G₂ may be a spacing between the second via 352 and the third via 353. The first gap G₁ may be different from the second gap G₂. For example, the first gap G₁ may be less than the second gap G₂.

The first via 351 may include a plurality of first convex portions 3511 stacked on one another. Each of the first convex portions 3511 may have a first vertical width V₁. The second via 352 may include a plurality of second convex portions 3521 stacked on one another. Each of the second convex portions 3521 may have a second vertical width V₂. The third via 353 may include a plurality of third convex portions 3531 stacked on one another. Each of the third convex portions 3531 may have a third vertical width V₃. The first vertical width V₁ may be greater than the second vertical width V₂. The second vertical width V₂ may be greater than the third vertical width V₃.

As shown in FIG. 2, a third gap G₃ may be a spacing between the first via 351 and the lateral surface 39 of the electronic device 3. A fourth gap G₄ may be a spacing between the connecting pad 36 and an imaginary extension of the lateral surface 39 of the electronic device 3. A fifth gap G₅ may be a spacing between the wire-bonding pad 34 and the imaginary extension of the lateral surface 39 of the electronic device 3. The third gap G₃, the fourth gap G₄ and the fifth gap G₅ may be different from each other. For example, the third gap G₃ may be less than the fourth gap G₄. The fourth gap G₄ may be less than the fifth gap G₅. Thus, the first via 351 and the connecting pad 36 are closer to the lateral surface 39 of the electronic device 3 than the wire-bonding pad 34 is.

FIG. 2A illustrates a cross-sectional view of a package structure 1′ according to some embodiments of the present disclosure. The package structure 1′ of FIG. 2A may be similar to the package structure 1 of FIG. 1 and FIG. 2, except that electronic device 3 may slightly tilt with respect to the carrier 2.

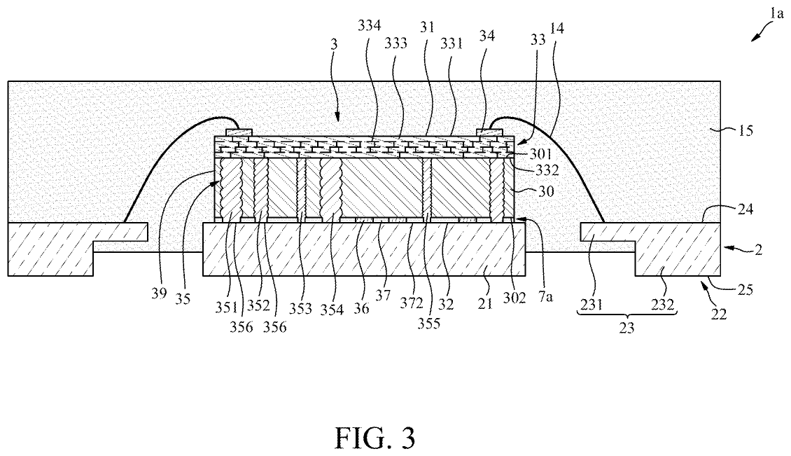

FIG. 3 illustrates a cross-sectional view of a package structure 1a according to some embodiments of the present disclosure. The package structure 1a of FIG. 3 may be similar to the package structure 1 of FIG. 1 and FIG. 2, and the differences therebetween are described as follows. The package structure 1a of FIG. 3 may be similar to the package structure 1 of FIG. 1 except for the structure of the level-maintaining structure 7a. As shown in FIG. 3, the level-maintaining structure 7a may include a plurality of dummy pads 36 and the protrusion portions 350 of the vias 35. The package structure 1a may further include a dielectric layer 37. The dummy pads 36 of FIG. 3 may be same as or similar to the dummy pads 36 of FIG. 3. The dummy pads 36 (or bumps or posts) may be disposed adjacent to or disposed on the second surface 302 (e.g., the bottom surface) of the main body 30. The dummy pads 36 may include a metal material such as copper, aluminum or gold. Further, the dummy pads 36 may protrude from the second surface 302 (e.g., the bottom surface) of the main body 30.

The dielectric layer 37 may be a bonding layer, an adhesive layer or a buffer layer. The dielectric layer 37 may be disposed adjacent to or disposed on the second surface 302 (e.g., the bottom surface) of the main body 30. The dielectric layer 37 may be disposed between the electronic device 3 and the carrier 2. The dielectric layer 37 may surround the dummy pads 36. The dummy pads 36 and the protrusion portions 350 of the vias 35 may be disposed in the dielectric layer 37. In some embodiments, the dummy pads 36 may extend through the dielectric layer 37. In some embodiments, the bottom surfaces 362 of the dummy pads 36 may be substantially aligned with or level with the bottom surface 372 of the dielectric layer 37. Thus, the bottom surfaces 362 of the dummy pads 36 may be exposed by the dielectric layer 37. The bottom surface 372 of the dielectric layer 37 may be substantially level or aligned with the bottom surfaces 356 of the vias 35 (e.g., the first via 351, the second via 352 and the third via 353). The bottom surfaces 362 of the dummy pads 36, the bottom surfaces 356 of the vias 35 and the bottom surface 372 of the dielectric layer 37 may directly contact the first portion 21 of the carrier 2. For example, the dummy pads 36 and the protrusion portions 350 of the vias 35 may be bonded to the first portion 21 of the carrier 2 through metal-to-metal bonding. Thus, the protrusion portions 350 of the vias 35 may be electrically connected to the first portion 21 of the carrier 2 directly.

In some embodiments, the level-maintaining structure 7a (including the dummy pads 36 and the protrusion portions 350 of the vias 35) may be a portion of the electronic device 3. Thus, the second surface 32 (e.g., the bottom surface) of the electronic device 3 may include the bottom surfaces 362 of the dummy pads 36, the protrusion portions 350 of the vias 35 and the bottom surface 372 of the dielectric layer 37. The second surface 32 (e.g., the bottom surface) of the electronic device 3 may directly contact the first portion 21 of the carrier 2.

In some embodiments, the level-maintaining structure 7a (including the dummy pads 36 and the protrusion portions 350 of the vias 35) may be substantially evenly distributed in the space between the main body 30 of the electronic device 3 and the first portion 21 of the carrier 2. After the metal-to-metal bonding process conducted to the dummy pads 36 and the protrusion portions 350 of the vias 35 and the first portion 21 of the carrier 2, the joints formed therebetween may be solidified, thus, the gap between the second surface 302 (e.g., the bottom surface) of the main body 30 and the top surface 24 of the first portion 21 of the carrier 2 may be fixed and consistent. As a result, the level-maintaining structure 7a may maintain or keep the level of the first surface 31 (e.g., the top surface or the active surface) of the electronic device 3. The level-maintaining structure 7a may be configured to ensure that the entire first surface 31 (e.g., the top surface or the active surface) of the electronic device 3 is at a same elevation. The first surface 31 (e.g., the top surface or the active surface) of the electronic device 3 may be substantially parallel with the top surface 24 of the carrier 2, so as to facilitate the wire-bonding process.

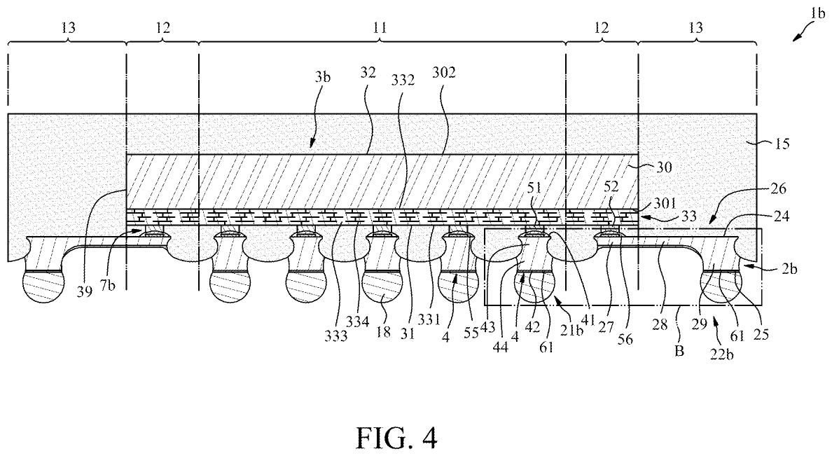

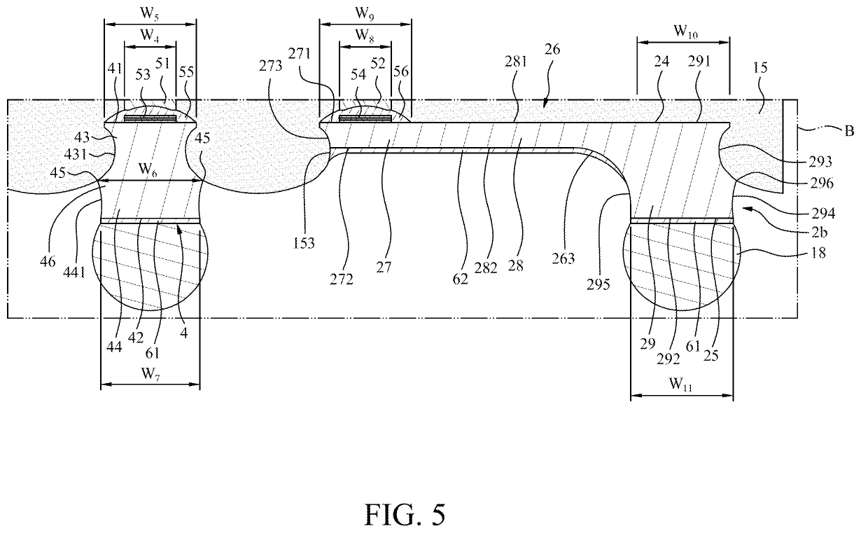

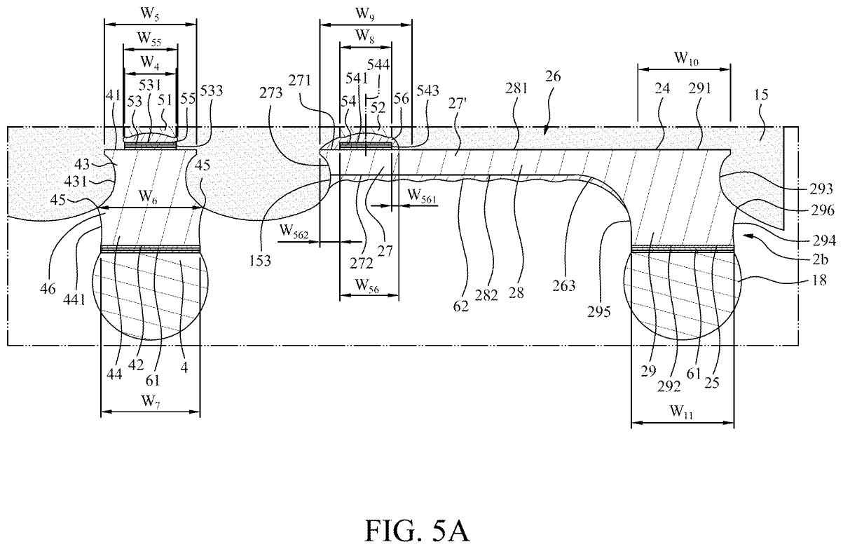

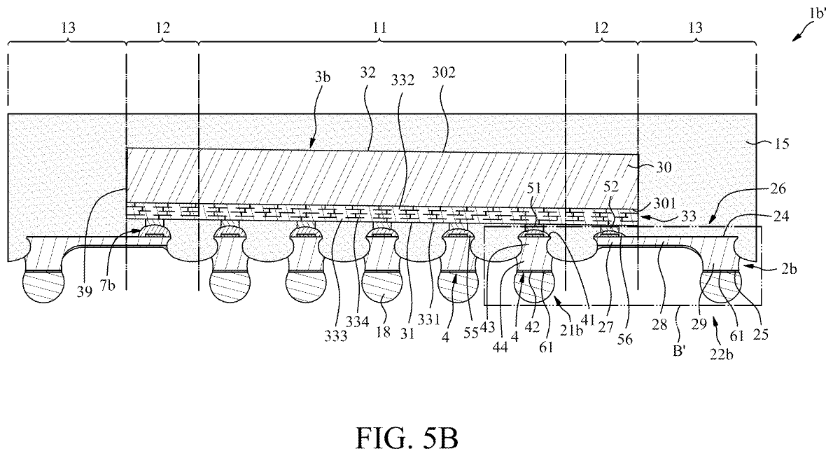

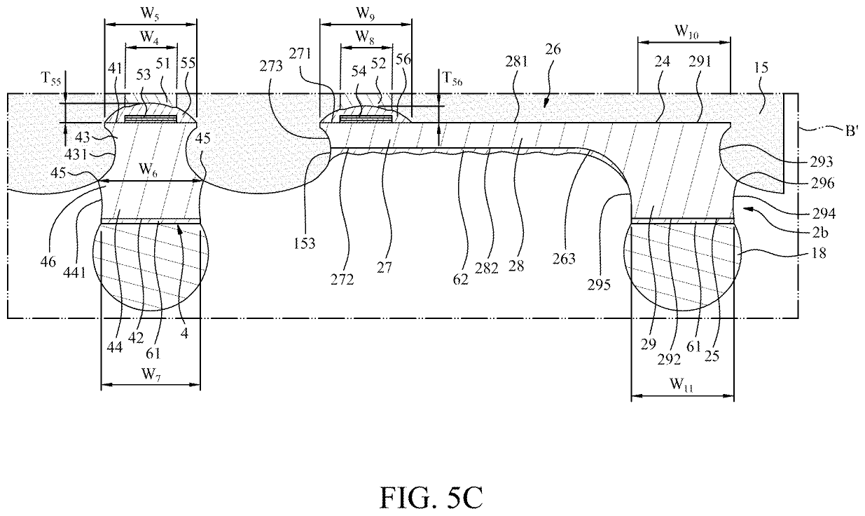

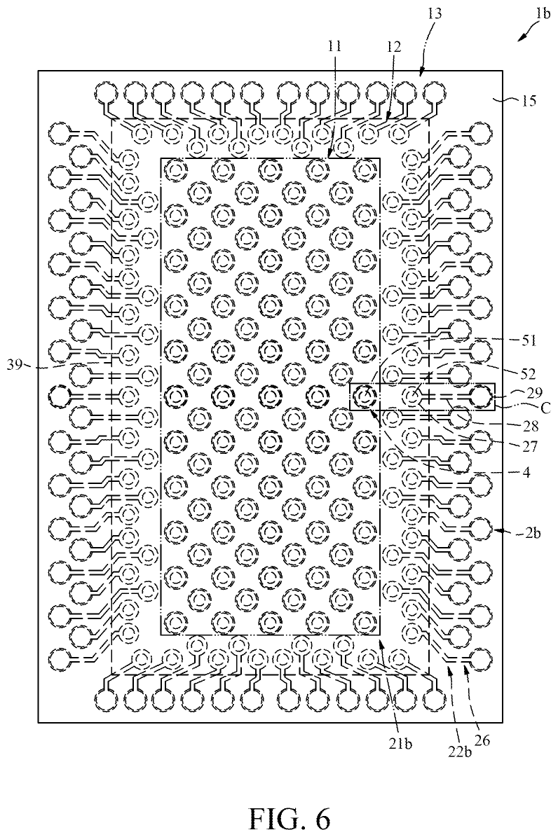

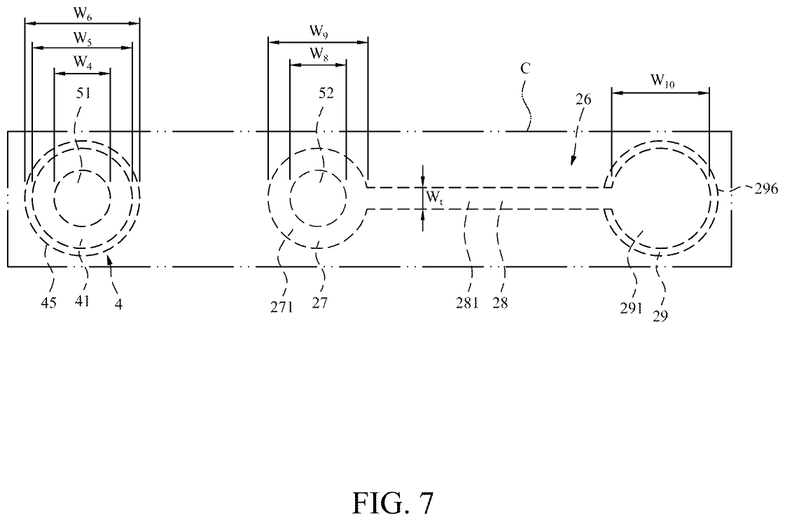

FIG. 4 illustrates a cross-sectional view of a package structure 1b according to some embodiments of the present disclosure. FIG. 5 illustrates a partially enlarged view of a region “B” in FIG. 4. FIG. 5A illustrates a partially enlarged view of a region of a package structure according to some embodiments of the present disclosure. FIG. 5B illustrates a cross-sectional view of a package structure 1b′ according to some embodiments of the present disclosure. FIG. 5C illustrates a partially enlarged view of a region “B” in FIG. 5B. FIG. 6 illustrates a top view of the package structure 1b of FIG. 4. FIG. 7 illustrates a partially enlarged view of a region “C” in FIG. 6. The package structure 1b may be an electronic package structure or a semiconductor package structure. The package structure 1b, 1b′ may include a carrier 2b, an electronic device 3b, a level-maintaining structure 7b, an encapsulant 15 and a plurality of solder balls 18.

As shown in FIG. 4 and FIG. 5, the carrier 2b may be or may include a lead frame, and may include a first portion 21b and a second portion 22b electrically insulated from the first portion 21b. The carrier 2b may include a metal material such as copper. The carrier 2b may have a top surface 24 and a bottom surface 25 opposite to the top surface 24. The second portion 22b may be separated from or spaced apart from the first portion 21b. The second portion 22b and the first portion 21b may be formed concurrently after an etching process. The first portion 21b may include a plurality of first connecting elements 4 (e.g., terminals 4, pins 4, bumps 4 or pads 4) separated from or spaced apart from each other. The first connecting elements 4 may be ground pads. Thus, the first portion 21b (including the first connecting elements 4) may be used for electrically grounding. Thus, the first portion 21b (including the first connecting elements 4) may be a portion of a grounding path. The grounding path may pass through or extend through the first portion 21b (including the first connecting elements 4), and may not pass through or extend through the second portion 22b.

In some embodiments, the first connecting element 4 may correspond to a first bump 51 of the electronic device 3b. The first connecting element 4 may have a first surface 41 (e.g., a top surface) and a second surface 42 (e.g., a bottom surface) opposite to the first surface 41 (e.g., the top surface). In some embodiments, the first surface 41 (e.g., the top surface) and the second surface 42 (e.g., the bottom surface) of the first connecting element 4 may be the top surface 24 and the bottom surface 25 of the carrier 2b respectively. In some embodiments, the first connecting element 4 may include an upper portion 43, a lower portion 44 and an apex edge 45 disposed between the upper portion 43 and the lower portion 44. The upper portion 43 may have an upper lateral surface 431. The lower portion 44 may have a lower lateral surface 441. Both of the upper lateral surface 431 and the lower lateral surface 441 are curved surfaces such as concave surfaces. The upper lateral surface 431 and the lower lateral surface 441 may intersect at the apex edge 45. Thus, a shape of a protrusion portion 46 of the first connecting element 4 near the apex edge 45 may be a bird's beak. The protrusion portion 46 may be collectively defined by a lower portion of the upper lateral surface 431 and an upper portion of the lower lateral surface 441.

The upper lateral surface 431 may extend between the first surface 41 (e.g., the top surface) and the apex edge 45. The lower lateral surface 441 may extend between the apex edge 45 and the second surface 42 (e.g., the bottom surface). A curvature of the upper lateral surface 431 may be different from a curvature of the lower lateral surface 441. The upper portion 43 may include a neck portion. A top end of the upper portion 43 may have a fifth width W₅ (or a diameter). A bottom end of the upper portion 43 may have a sixth width W₆ (or a diameter). The sixth width W₆ may be also defined by the apex edge 45. A top end of the lower portion 44 may have the sixth width W₆. A bottom end of the lower portion 44 may have a seventh width W₇ (or a diameter). The fifth width W₅ may be less than the sixth width W₆. The seventh width W₇ may be less than the sixth width W₆, and may be greater than the fifth width W₅. A thickness of the upper portion 43 may be different from a thickness of the lower portion 44. For example, the thickness of the upper portion 43 may be greater than the thickness of the lower portion 44. In addition, the first bump 51 may have a fourth width W₄ that is less than the fifth width W₅.

In addition, the second portion 22b may include a plurality of leads 26 disposed around the first portion 21b. The leads 26 may be separated from or spaced apart from each other. The second portion 22b (e.g., the leads 26) may be used for transmitting signals. Thus, the second portion 22b (e.g., the leads 26) may be a portion of a signal transmission path. The signal transmission path may pass through or extend through the second portion 22b (e.g., the leads 26), and may not pass through or extend through the first portion 21b. In some embodiments, each of the leads 26 of the second portion 22b may include a second connecting element 27, a trace 28 and a third connecting element 29. In some embodiments, the second connecting element 27 may correspond to a second bump 52 of the electronic device 3b. The second connecting element 27 may be a pin, a bump or a pad. The second connecting element 27 may have a top surface 271, a bottom surface 272 opposite to the top surface 271 and a lateral surface 273 extending between the top surface 271 and the bottom surface 272. The lateral surface 273 may be a curved surface such as a concave surface. A top end of the second connecting element 27 may have a ninth width W₉ (or a diameter). The ninth width W₉ may be equal to or less than the fifth width W₅. In addition, the second bump 52 may have an eighth width W₈ that is less than the ninth width W₉.

The trace 28 connects the second connecting element 27 and the third connecting element 29. The trace 28 may have a top surface 281 and a bottom surface 282 opposite to the top surface 281. The third connecting element 29 may be a pin, a bump or a pad, and may be configured for external connection. The third connecting element 29 may have a top surface 291 and a bottom surface 292 opposite to the top surface 291. The third connecting element 29 may have a first lateral surface 293, a second lateral surface 294 and a third lateral surface 295. All of the first lateral surface 293, the second lateral surface 294 and the third lateral surface 295 may be curved surfaces such as concave surfaces. The first lateral surface 293 and the second lateral surface 294 may extend between the top surface 291 and the bottom surface 292. The third lateral surface 295 may extend between the bottom surface 282 of the trace 28 and the bottom surface 292. A curvature of the first lateral surface 293, a curvature of the second lateral surface 294 and a curvature of the third lateral surface 295 may be different from each other. In some embodiments, the curvature of the second lateral surface 294 may be equal to the curvature of the third lateral surface 295. A top end of the third connecting element 29 may have a tenth width W₁₀ (or a diameter). The tenth width W₁₀ may be equal to or greater than the fifth width W₅ or the ninth width W₉. A bottom end of the third connecting element 29 may have an eleventh width W₁₁ (or a diameter). The eleventh width W₁₁ may be equal to or less than the tenth width W₁₀. The first lateral surface 293 and the second lateral surface 294 may intersect at an apex edge 296. Thus, a shape of a protrusion portion of the third connecting element 29 near the apex edge 296 may be a bird's beak. The protrusion portion may be collectively defined by a lower portion of the first lateral surface 293 and an upper portion of the second lateral surface 294.

The second connecting element 27, the trace 28 and the third connecting element 29 may be formed concurrently and integrally as a monolithic structure. The top surface 24 of the carrier 2b may include the top surface 271 of the second connecting element 27, the top surface 281 of the trace 28 and the top surface 291 of the third connecting element 29. The bottom surface 25 of the carrier 2b may include the bottom surface 292 of the third connecting element 29. An elevation of the apex edge 296 may be same as an elevation of the apex edge 45, and may be lower than an elevation of the bottom surface 282 of the trace 28 and an elevation of the bottom surface 272 of the second connecting element 27. A thickness of the second connecting element 27 may be equal to a thickness of the trace 28, and may be less than a thickness of the third connecting element 29. As shown in FIG. 7, a width W₁ of the trace 28 may be less the tenth width W₁₀ and the ninth width W₉.

As shown in FIG. 4 and FIG. 5, the electronic device 3b may be disposed over the first portion 21b of the carrier 2b. The electronic device 3b may be disposed on the first portion 21b of the carrier 2b and a portion of the second portion 22b of the carrier 2b. The electronic device 3b may have a first surface 31 (e.g., a bottom surface or an active surface), a second surface 32 (e.g., a top surface or a backside surface) and a lateral surface 39. The second surface 32 (e.g., a top surface or a backside surface) is opposite to the first surface 31 (e.g., the bottom surface or the active surface). The lateral surface 39 extends between the first surface 31 and the second surface 32. The electronic device 3b may include a main body 30 and an active circuit structure 33. The main body 30 may include a semiconductor material such as silicon, and may have a first surface 301 (e.g., a bottom surface) and a second surface 302 (e.g., a top surface) opposite to the first surface 301 (e.g., the bottom surface).

The active circuit structure 33 may be disposed adjacent to the first surface 31 (e.g., the bottom surface or the active surface) of the electronic device 3b. The active circuit structure 33 may be disposed on the first surface 301 (e.g., the bottom surface) of the main body 30, and may have a first surface 331 (e.g., a bottom surface) and a second surface 332 (e.g., a top surface) opposite to the first surface 331 (e.g., the bottom surface). Thus, the second surface 332 (e.g., the top surface) of the active circuit structure 33 may contact the first surface 301 (e.g., the bottom surface) of the main body 30. Further, the active circuit structure 33 may include a dielectric structure 333 and a plurality of circuit layers 334 embedded in the dielectric structure 333. For example, the dielectric structure 333 may include a plurality of dielectric layers stacked on one another. The circuit layers 334 may be or may include a front-end-of-line (FEOL), a middle-of-line (MOL) and/or a back-end-of-line (BEOL).

The level-maintaining structure 7b may be disposed between the main body 30 of the electronic device 3b and the carrier 2, and may electrically connect the main body 30 of the electronic device 3 and the carrier 2. The level-maintaining structure 7b may be configured to maintain or keep a level of the first surface 31 (e.g., the bottom surface or the active surface) of the electronic device 3b. The level-maintaining structure 7b may include a conductive material such as metal. Thus, the level-maintaining structure 7b may be not only a bonding layer, or an adhesive layer. In some embodiments, the level-maintaining structure 7b may include a plurality of first bumps 51, a plurality of second bumps 52, a plurality of first pads 53, a plurality of second pads 54, a plurality of first reflowable materials 55 and a plurality of second reflowable materials 56.

The first bumps 51 and the second bumps 52 may be disposed adjacent to or disposed on the first surface 31 (e.g., the bottom surface or the active surface) of the electronic device 3.

The first bumps 51 and the second bumps 52 may include a metal material such as copper, aluminum or gold. For example, the first bumps 51 and the second bumps 52 may be electrically connected to the circuit layers 334 of the active circuit structure 33. Further, the first bumps 51 and the second bumps 52 may protrude from the first surface 331 of the active circuit structure 33. The first reflowable materials 55 and the second reflowable materials 56 may include a soldering metal material such as a tin-silver (SnAg) alloy, a tin-copper (SnCu) alloy, or a gold-tin (AuSn) alloy. The first reflowable material 55 may be also referred to as “a first solder”. The second reflowable material 56 may be also referred to as “a second solder”.

The first reflowable materials 55 may connect the first bumps 51 to the first portion 21b (including the first connecting elements 4) of the carrier 2b. Thus, the first bumps 51 may be electrically connected to the first portion 21b of the carrier 2b through the first reflowable materials 55. In addition, the second reflowable materials 56 may connect the second bumps 52 to the second portion 22b (including the second connecting elements 27 of the leads 26) of the carrier 2b. Thus, the second bumps 52 may be electrically connected to the second portion 22b of the carrier 2b through the second reflowable materials 56. In some embodiments, the first bumps 51 and the second bumps 52 may be a portion of the electronic device 3b. In some embodiments, the first pad 53 may be disposed on or adjacent to the first surface 41 (e.g., the top surface) of the first connecting element 4 and covered by the first reflowable material 55 so as to facilitate the bonding between the first reflowable material 55 and the first connecting element 4. The first pad 53 may be also referred to as “an upper pad” or “a first upper pad”. The first pad 53 may be a three-layered structure, and may include a nickel (Ni) layer, a palladium (Pd) layer and a gold (Au) layer in sequence. In some embodiments, the second pad 54 may be disposed on the first surface 271 (e.g., the top surface) of the second connecting element 27 and covered by the second reflowable material 56 so as to facilitate the bonding between the second reflowable material 56 and the second connecting element 27. The second pad 54 may be also referred to as “an upper pad” or “a second upper pad”. The second pad 54 may be a three-layered structure, and may include a nickel (Ni) layer, a palladium (Pd) layer and a gold (Au) layer in sequence.

In some embodiments, the level-maintaining structure 7b (including the first bumps 51, the second bumps 52, the first reflowable materials 55 and the second reflowable materials 56) may be substantially evenly distributed in the space between the electronic device 3b and the carrier 2b. In a reflow process, the first reflowable materials 55 and the second reflowable materials 56 may be melted, and the first surface 31 of the electronic device 3b may remain horizontal with respect to the top surface 24 of the carrier 2b. After the reflow process, the first reflowable materials 55 and the second reflowable materials 56 may be solidified, thus, the gap between the first surface 31 of the electronic device 3b and the top surface 24 of the first portion 21b of the carrier 2b may be fixed and consistent. As a result, the level-maintaining structure 7b may maintain or keep the level of the first surface 31 of the electronic device 3b.

The active circuit structure 33 of the electronic device 3b may be electrically connected to the first portion 21b (including the first connecting elements 4) of the carrier 2b through the first bumps 51 and the first reflowable materials 55 so as to transmit noise current. Each of the first connecting elements 4 may be a ground pad or ground pin. In addition, the active circuit structure 33 of the electronic device 3b may be electrically connected to the second portion 22b (including the leads 26) of the carrier 2b through the second bumps 52 and the second reflowable materials 56 so as to transmit signals. Thus, the noise current in the active circuit structure 33 of the electronic device 3b may flow to the first portion 21b (including the first connecting elements 4) of the carrier 2b through the first bumps 51 and the first reflowable materials 55. In addition, the signals of the active circuit structure 33 of the electronic device 3b may be transmitted to the second portion 22b of the carrier 2b through the second bumps 52 and the second reflowable materials 56. Therefore, the noise current of the package structure 1b may be eliminated or reduced, and the performance of the package structure 1b may be improved.

The encapsulant 15 (e.g., a molding compound with or without fillers) may encapsulate and cover the electronic device 3b, the level-maintaining structure 7b (including the first bumps 51, the second bumps 52, the first reflowable materials 55 and the second reflowable materials 56) and a portion of the carrier 2b. For example, the encapsulant 15 may cover and contact the upper portion 43 of the first connecting element 4, the second connecting element 27, the trace 28 and an upper portion of the third connecting element 29. Thus, the lower portion 44 of the first connecting element 4, the bottom surface 272 of the second connecting element 27, the bottom surface 282 of the trace 28 and a lower portion of the third connecting element 29 may be exposed by the encapsulant 15. A portion of the encapsulant 15 may extend into a gap between the first portion 21b of the carrier 2b and the second portion 22b of the carrier 2b, and may extend into a gap between the first connecting elements 4.

In some embodiments, a plurality of conductive layers 61 may be formed or disposed on the bottom surface 42 of the first connecting element 4 and the bottom surface 292 of the third connecting element 29 for external connection. Further, a protection layer 62 (e.g., a solder mask or a solder resist layer) may be formed or disposed on the lower lateral surface 441 of the lower portion 44 of the first connecting element 4, the bottom surface 272 of the second connecting element 27, the bottom surface 282 of the trace 28, the second lateral surface 294 of the third connecting element 29 and the third lateral surface 295 of the third connecting element 29 so as to prevent such areas from being contacted by a solder material. The solder balls 18 may be disposed on the conductive layers 61 for external connection.

As shown in FIG. 4 and FIG. 6, the package structure 1b may include a first region 11, a second region 12 and a third region 13. The second region 12 may surround the first region 11, and the third region 13 may surround the second region 12. The first region 11 may be a center region 11. The second region 12 may be an intermediate region 12 between the first region 11 and the third region 13 from a top view. The third region 13 may be a periphery region 13. The first region 11 may be the region that the first connecting elements 4 and the first bumps 51 are disposed in. Thus, the first connecting elements 4 and the first bumps 51 may be disposed within the first region 11. The first region 11 may be a ground region. The second region 12 may be the region that the second connecting elements 27 and the second bumps 52 are disposed in. Thus, the second connecting elements 27 and the second bumps 52 may be disposed within the second region 12. The third region 13 may be the region that the third connecting elements 29 are disposed in. Thus, the third connecting elements 29 may be disposed within the third region 13. The second region 12 and the third region 13 may be a signal transmitting region. A distribution density of the first connecting elements 4 in the first region 11 may be equal to, less than or greater than a distribution density of the second connecting elements 27 in the second region 12. The distribution density of the first connecting elements 4 in the first region 11 and the distribution density of the second connecting elements 27 in the second region 12 may be greater than a distribution density of the third connecting elements 29 in the third region 13. The distribution densities of the first connecting elements 4, the second connecting elements 27 and the third connecting elements 29 are defined as a quantity of the first connecting elements 4, the second connecting elements 27 and the third connecting elements 29 in an unit area of the carrier 2b.

The structure of FIG. 5A is similar to the structure of FIG. 5, and the differences therebetween are described as follows. The first reflowable material 55 (e.g., the first solder 55) may be disposed on a top surface 531 of the first pad 53 (e.g., the first upper pad), and free from contacting a lateral surface 533 of the first pad 53. Since the first pad 53 (e.g., the first upper pad) may include a nickel (Ni) layer, a palladium (Pd) layer and a gold (Au) layer in sequence, the bonding force between the first pad 53 and the first solder 55 is increased or improved, and the cohesion force of the first solder 55 is also increased or improved. The first pad 53 (e.g., the first upper pad) may be configured to reduce or inhibit or minimize a lateral overflow of the first reflowable material 55 (e.g., the first solder 55). That is, the first reflowable material 55 (e.g., the first solder 55) does not contact the lateral surface 533 of the first pad 53, and the first pad 53 (e.g., the first upper pad) is configured to prevent the first reflowable material 55 from lateral bleeding. The first reflowable material 55 is limited or constrained to a position above the top surface 531 of the first pad 53.

The second reflowable material 56 (e.g., the second solder 56) may cover the second pad 54 (e.g., the second upper pad), and may contact the top surface 24 of the carrier 2b. For example, the second reflowable material 56 (e.g., the second solder 56) may cover a top surface 541 and a lateral surface 543 of the second pad 54 (e.g., the second upper pad). The second solder 56 may be asymmetric with respect to a center axis 544 of the second upper pad 54. A width W₅₆₁ of a first portion of the second solder 56 disposed at a first side (e.g., the right side) of the second upper pad 54 is different from a width W₅₆₂ of a second portion of the second solder 56 disposed at a second side (e.g., the left side) of the second upper pad 54. That is, the two widths W₅₆₁, W₅₆₂ of two portions of the second solder 56 that are disposed at two opposite sides of the second upper pad 54 are different from each other. In addition, a width W₅₅ of the first solder 55 may be different from a width W₅₆ of the second solder 56. The width W₅₆ of the second solder 56 is greater than the width W₅₅ of the first solder 55, and the second solder 56 is closer to a periphery edge 296 of the carrier 2b than the first solder 55 is.

The lead 26 may taper downward, and may have a contact surface 292 and a lower surface 263. The contact surface 292 may be the bottom surface 292 of the third connecting element 29. The lower surface 263 may be outside the contact surface 292 and may extend from a thicker end 29 (e.g., the third connecting element 29) to a thinner end 27′ (including the second connecting element 27 and the trace 28). The lower surface 263 may include the bottom surface 272 of the second connecting element 27, the bottom surface 282 of the trace 28 and the third lateral surface 295 of the third connecting element 29. The protection layer 62 (e.g., the solder mask) may be disposed on the lower surface 263 and may expose a portion of the lower surface 263. That is, the protection layer 62 (e.g., the solder mask) may partially cover the lower surface 263. The protection layer 62 (e.g., the solder mask) may partially cover the encapsulant 15 between the first connecting element 4 (e.g., the terminal 4) and the lead 26. For example, the protection layer 62 (e.g., the solder mask) may cover a portion 153 of the encapsulant 15. The protection layer 62 (e.g., the solder mask) may have an inconsistent thickness. The protection layer 62 (e.g., the solder mask) may taper toward the contact surface 292.

The package structure 1b′ of FIG. 5B may be similar to the package structure 1b of FIG. 4 and FIG. 5, except that electronic device 3b may slightly tilt with respect to the carrier 2b. Thus, as shown in FIG. 5C, a maximum thickness T₅₅ of the first solder 55 may be different from a maximum thickness T₅₆ of the second solder 56 in a cross-sectional view. For example, the maximum thickness T₅₅ of the first solder 55 may be greater than the maximum thickness T₅₆ of the second solder 56.

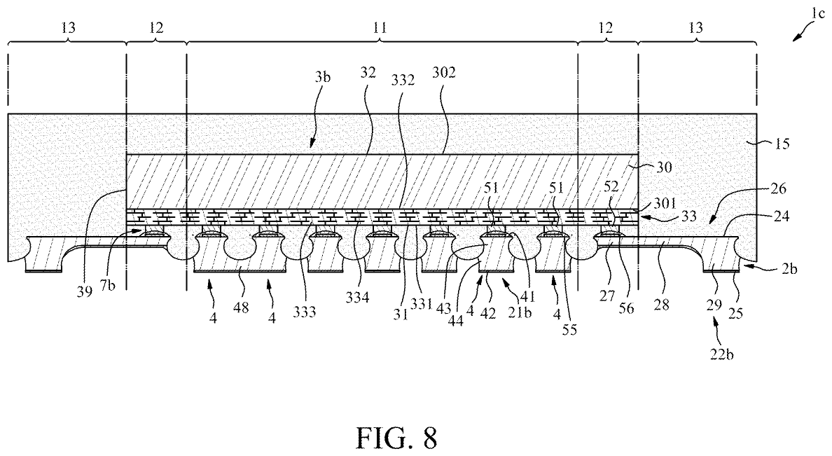

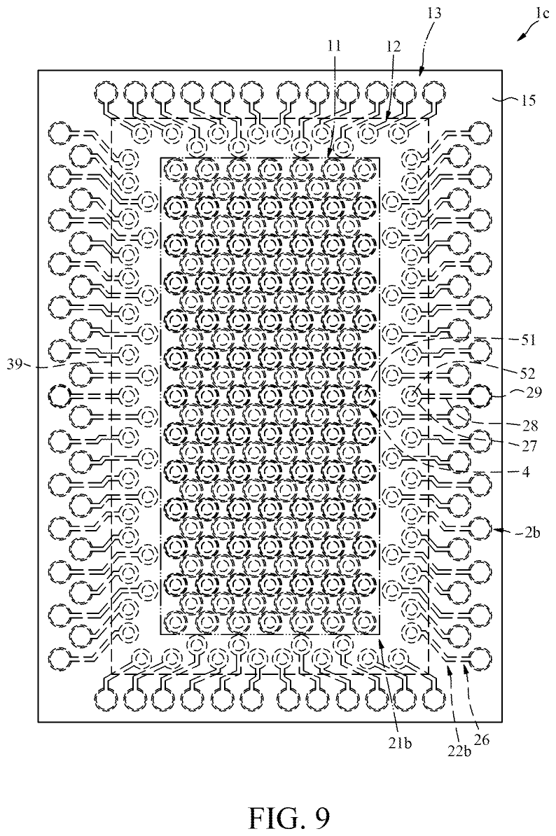

FIG. 8 illustrates a cross-sectional view of a package structure 1c according to some embodiments of the present disclosure. FIG. 9 illustrates a top view of the package structure 1c of FIG. 8. The package structure 1c of FIG. 8 and FIG. 9 is similar to the package structure 1b of FIG. 4 to FIG. 7, and the differences therebetween are described as follows. The distribution density of the first connecting elements 4 in the first region 11 of FIG. 9 may be greater than the distribution density of the first connecting elements 4 in the first region 11 of FIG. 6. The distribution or arrangement of the first connecting elements 4 in the first region 11 of FIG. 9 may be denser than the distribution or arrangement of the first connecting elements 4 in the first region 11 of FIG. 6. As shown in FIG. 9, the distribution density of the first connecting elements 4 in the first region 11 may be greater than the distribution density of the second connecting elements 27 in the second region 12. The distribution or arrangement of the first connecting elements 4 in the first region 11 may denser than the distribution or arrangement of the second connecting elements 27 in the second region 12. Further, the distribution density of the second connecting elements 27 in the second region 12 may be greater than the distribution density of the third connecting elements 29 in the third region 13. The distribution or arrangement of the second connecting elements 27 in the second region 12 may be denser than the distribution or arrangement of the third connecting elements 29 in the third region 13. In addition, two of the first connecting elements 4 may be physically connected to each other through a connection portion 48.

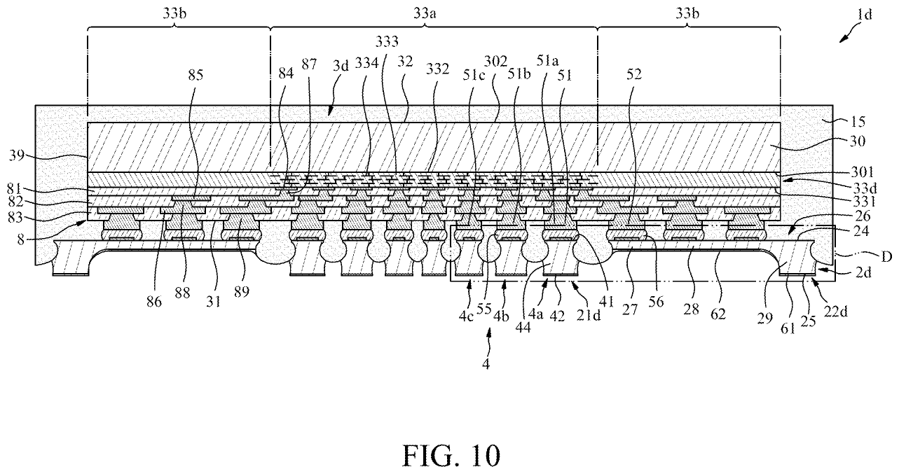

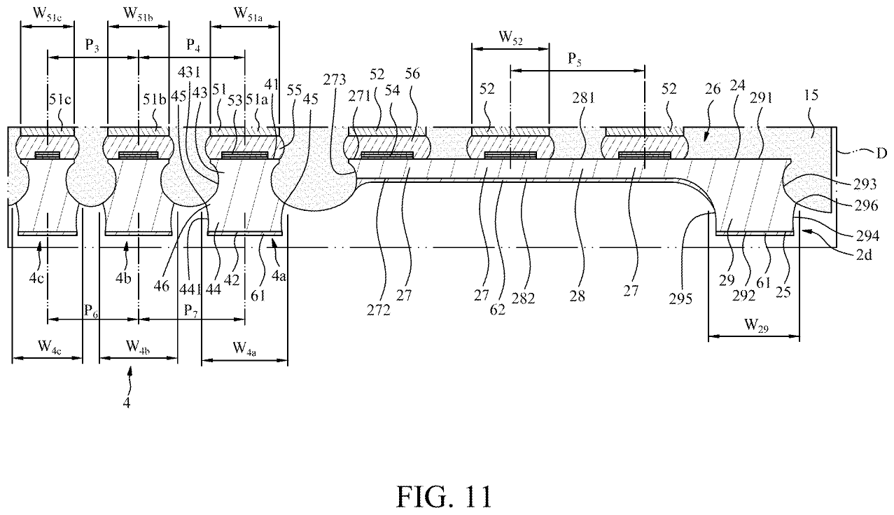

FIG. 10 illustrates a cross-sectional view of a package structure 1d according to some embodiments of the present disclosure. FIG. 11 illustrates a partially enlarged view of a region “D” in FIG. 10. The package structure 1d of FIG. 10 and FIG. 11 is similar to the package structure 1b of FIG. 4 to FIG. 7, and the differences therebetween are described as follows.

The electronic device 3d of FIG. 10 may include an active circuit structure 33d, a redistribution structure 8, a plurality of first bumps 51 and a plurality of second bumps 52. The active circuit structure 33d may a circuit region 33a and a non-circuit region 33b around the circuit region 33a. Thus, the electronic device 3d may the circuit region 33a and the non-circuit region 33b. The circuit layers 334 of the active circuit structure 33 may only be disposed within the circuit region 33a, and may not extend to the non-circuit region 33b. Thus, there may be a portion of the dielectric structure 333 in the non-circuit region 33b. There may be no circuit layer or electrical path within the non-circuit region 33b.

The redistribution structure 8 may be disposed on the first surface 331 (e.g., the bottom surface) of the active circuit structure 33d. The bottom surface of the redistribution structure 8 may be the first surface 31 (e.g., the bottom surface or the active surface) of the electronic device 3d. The redistribution structure 8 may be a fan-out circuit structure. The redistribution structure 8 may include a first dielectric layer 81, a second dielectric layer 82, a third dielectric layer 83, a first circuit layer 84, a second circuit layer 85, a third circuit layer 86, a plurality of first inner vias 87, a plurality of second inner vias 88, a plurality of third inner vias 89. The first circuit layer 84 may be disposed on the first surface 331 (e.g., the bottom surface) of the active circuit structure 33d and may be electrically connected to the circuit layers 334 of the active circuit structure 33. The first circuit layer 84 may only be disposed within the circuit region 33a. The first dielectric layer 81 may cover the first circuit layer 84 and the first surface 331 (e.g., the bottom surface) of the active circuit structure 33d. The second circuit layer 85 may be disposed on the first dielectric layer 81. The first inner vias 87 may extend through the first dielectric layer 81, and may electrically connect the first circuit layer 84 and the second circuit layer 85.

The second dielectric layer 82 may cover the second circuit layer 85 and the first dielectric layer 81. The third circuit layer 86 may be disposed on the second dielectric layer 82. The second inner vias 88 may extend through the second dielectric layer 82, and may electrically connect the second circuit layer 85 and the third circuit layer 86. The third dielectric layer 83 may cover the third circuit layer 86 and the second dielectric layer 82. The first bumps 51 and the second bumps 52 may be disposed on the third dielectric layer 83. The third inner vias 89 may extend through the third dielectric layer 83, and may electrically connect the third circuit layer 86 and the first bumps 51 and the second bumps 52.

A thickness of the third dielectric layer 83 may be greater than a thickness of the second dielectric layer 82. The thickness of the second dielectric layer 82 may be greater than a thickness of the first dielectric layer 81. Thus, a thickness of the dielectric layer 81, 82, 83 may increase toward the first surface 31 (e.g., the bottom surface or the active surface) of the electronic device 3d. Further, a thickness of the third circuit layer 86 may be greater than a thickness of the second circuit layer 85. The thickness of the second circuit layer 85 may be greater than a thickness of the first circuit layer 84. Thus, a thickness of the circuit layer 84, 85, 86 may increase toward the first surface 31 (e.g., the bottom surface or the active surface) of the electronic device 3d. In addition, a size (e.g., width) of the third inner via 89 may be greater than a size (e.g., width) of the second inner via 88. The size (e.g., width) of the second inner via 88 may be greater than a size (e.g., width) of the first inner via 87. Thus, a size (e.g., width) of the inner via 87, 88, 89 may increase toward the first surface 31 (e.g., the bottom surface or the active surface) of the electronic device 3d. The first inner vias 87, the second inner vias 88 and the third inner vias 89 may taper away from the first surface 31 (e.g., the bottom surface or the active surface) of the electronic device 3d.

The second bumps 52 may be disposed outside a vertical projection of the circuit region 33a. Thus, the circuit region 33a may not vertically overlap the second bumps 52. The non-circuit region 33b may vertically overlap the second bumps 52. Further, the first bumps 51 may be disposed within a vertical projection of the circuit region 33a. Thus, the circuit region 33a may vertically overlap the first bumps 51. The non-circuit region 33b may not vertically overlap the first bumps 51.

The circuit region 33a of the active circuit structure 33d of the electronic device 3d may be electrically connected to the first portion 21d (including the first connecting elements 4) of the carrier 2d through the redistribution structure 8 and the first bumps 51, so as to transmit noise current. Each of the first connecting elements 4 may be a ground pad or ground pin. In addition, the circuit region 33a of the active circuit structure 33d of the electronic device 3d may be electrically connected to the second portion 22d (including the leads 26) of the carrier 2d through the redistribution structure 8 and the second bumps 52 so as to transmit signals. Thus, the noise current in the active circuit structure 33d of the electronic device 3d may flow to the first portion 21d (including the first connecting elements 4) of the carrier 2d through the redistribution structure 8 and the first bumps 51. In addition, the signals of the active circuit structure 33d of the electronic device 3d may be transmitted to the second portion 22d of the carrier 2d through the redistribution structure 8 and the second bumps 52. Therefore, the noise current of the package structure 1d may be eliminated or reduced, and the performance of the package structure 1d may be improved.

In some embodiments, the first bumps 51 may include a first bump 51a (or a first part 51a), a first bump 51b (or a second part 51b) and a first bump 51c (or a third part 51c). The first bump 51a (or the first part 51a) may have a width W₅₁ₐ. The first bump 51b (or the second part 51b) may have a width W_{51b}. The first bump 51c (or the third part 51c) may have a width W_{51c}. The second bump 52 may have a width W₅₂. The width W₅₁ₐ may be greater than the width W_{51b}. The width W_{51b} may be greater than the width W_{51c}. The width W₅₂ may be greater than the width W₅₁ₐ. Thus, the first bumps 51 (e.g., the first bumps 51a, 51b, 51c) may have different or inconsistent widths. The width of the first bumps 51 may decrease toward the center of the electronic device 3d. A width of one of the first bumps 51 may be different from a width of one of the second bumps 52. The width W₅₂ of the second bump 52 may be greater than the width W₅₁ₐ of the first bump 51a.

A pitch P₃ may be a distance between a center of the first bump 51c (or the third part 51c) and a center of the first bump 51b (or the second part 51b). A pitch P₄ may be a distance between the center of the first bump 51b (or the second part 51b) and a center of the first bump 51a (or the first part 51a). A pitch P₅ may be a distance between the centers of two adjacent second bumps 52. The pitch P₃ may be less than the pitch P₄. The pitch P₄ may be less than the pitch P₅. Thus, the pitch of the first bumps 51 (e.g., the first bumps 51a, 51b, 51c) may be inconsistent. The pitch of the first bumps 51 (e.g., the first bumps 51a, 51b, 51c) may decrease toward the center of the electronic device 3d. The pitch (e.g., P₃ and P₄) of the first bumps 51 (e.g., the first bumps 51a, 51b, 51c) may be different from the pitch P₅ of the second bumps 52. For example, the pitch (e.g., P₃ and P₄) of the first bumps 51 (e.g., the first bumps 51a, 51b, 51c) may be less than the pitch P₅ of the second bumps 52. Therefore, a distribution density of the first bumps 51 (e.g., the first bumps 51a, 51b, 51c) may be different from a distribution density of the second bumps 52. For example, the distribution density of the first bumps 51 (e.g., the first bumps 51a, 51b, 51c) may be greater than the distribution density of the second bumps 52. A gap or spacing between the first bumps 51 (e.g., the first bumps 51a, 51b, 51c) may be different from a gap or spacing between the second bumps 52. For example, the gap or spacing between the first bumps 51 (e.g., the first bumps 51a, 51b, 51c) may be less than the gap or spacing between the second bumps 52.

In some embodiments, the first connecting elements 4 may correspond to the first bumps 51 of the electronic device 3d. The structure of each of the first connecting elements 4 may be the same as or similar to the structure of each of the first connecting elements 4 of FIG. 4 and FIG. 5. In some embodiments, the first connecting elements 4 may include a first pin 4a, a second pin 4b and a third pin 4c. The first bump 51a (or a first part 51a), the first bump 51b (or a second part 51b) and the first bump 51c (or a third part 51c) may connect to the first pin 4a, the second pin 4b and the third pin 4c, respectively, through the first reflowable materials 55.

The first pin 4a may have a maximum width W₄ₐ. The second pin 4b may have a maximum width W_{4b}. The third pin 4c may have a maximum width W_{4c}. The third connecting element 29 may have a maximum width W₂₉. The maximum width W₄ₐ may be greater than the maximum width W_{4b}. The maximum width W₄ may be greater than the maximum width W_{4c}. The maximum width W₂₉ may be greater than the maximum width W₄ₐ. Thus, the first connecting elements 4 (e.g., the first pin 4a, the second pin 4b and the third pin 4c) may have different or inconsistent widths. The width of the first connecting elements 4 may decrease toward the center of the electronic device 3d. A width of one of the first connecting elements 4 may be different from a width of one of the third connecting elements 29. The maximum width W₂₉ of the third connecting element 29 may be greater than the maximum width W₄ₐ of the first pin 4a.

A pitch P₆ may be a distance between a center of the third pin 4c and a center of the second pin 4b. A pitch P₇ may be a distance between the center of the second pin 4b and a center of the first pin 4a. The pitch P₆ may be less than the pitch P₇. Thus, the pitch of the first connecting elements 4 (e.g., the first pin 4a, the second pin 4b and the third pin 4c) may be inconsistent. The pitch of the first connecting elements 4 (e.g., the first pin 4a, the second pin 4b and the third pin 4c) may decrease toward the center of the electronic device 3d.

In some embodiments, the pitch of the first connecting elements 4 (e.g., the first pin 4a, the second pin 4b and the third pin 4c) may be the same as the pitch of the first bumps 51 (e.g., the first bumps 51a, 51b, 51c). For example, the pitch P₆ may be equal to the pitch P₃, and the pitch P₇ may be equal to the pitch P₄. Thus, a distribution density of the first connecting elements 4 (e.g., the first pin 4a, the second pin 4b and the third pin 4c) may be the same as the distribution density of the first bumps 51 (e.g., the first bumps 51a, 51b, 51c).

As shown in FIG. 11, the three second bumps 52 may be connected or bonded to three second connecting elements 27 on a same trace 28 of a lead 26. However, in other embodiments, the three second bumps 52 may be connected or bonded to three second connecting elements 27 on three separated traces 28 of three separated leads 26 respectively.

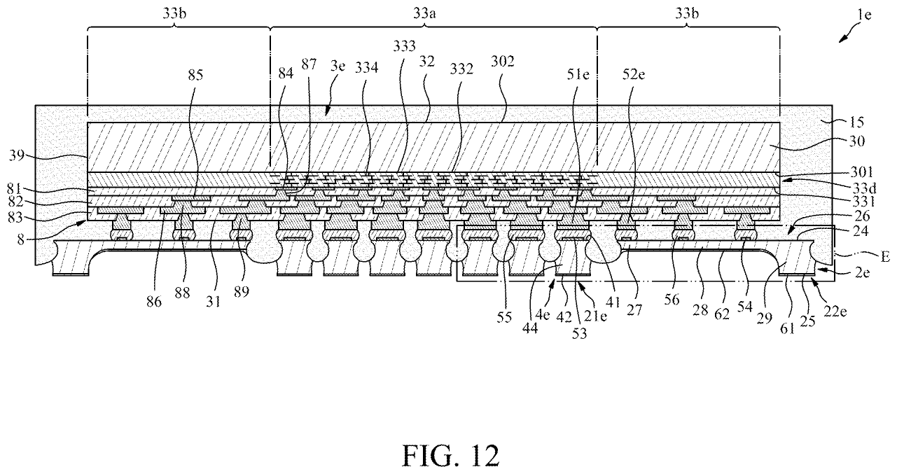

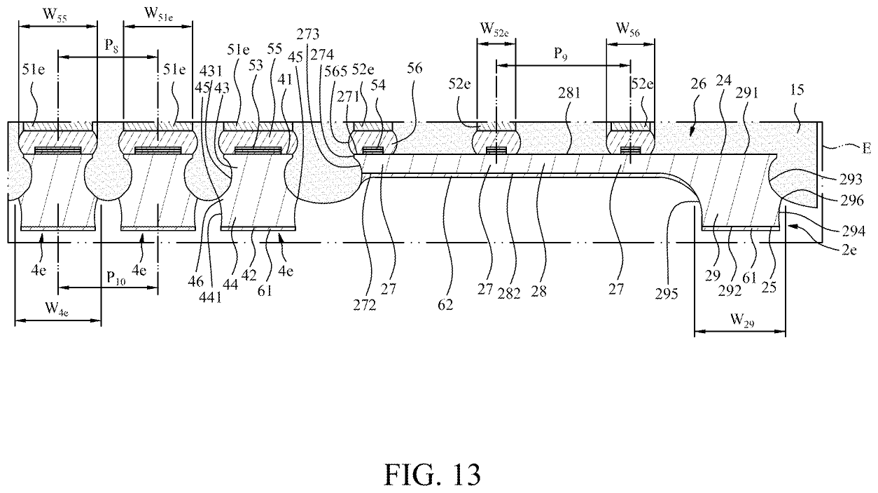

FIG. 12 illustrates a cross-sectional view of a package structure 1e according to some embodiments of the present disclosure. FIG. 13 illustrates a partially enlarged view of a region “E” in FIG. 12. The package structure 1e of FIG. 12 and FIG. 13 is similar to the package structure 1d of FIG. 10 and FIG. 11, and the differences therebetween are described as follows.

The package structure 1e may include a carrier 2e and an electronic device 3e. The carrier 2e may be similar to the carrier 2d of FIG. 10, and may include a first portion 21e and a second portion 22e electrically insulated from the first portion 21e. The second portion 22e may include a plurality of first connecting elements 4e. The electronic device 3e of FIG. 12 may include an active circuit structure 33d, a redistribution structure 8, a plurality of first bumps 51e and a plurality of second bumps 52e. The active circuit structure 33d may a circuit region 33a and a non-circuit region 33b around the circuit region 33a. Thus, the electronic device 3d may the circuit region 33a and the non-circuit region 33b. The circuit layers 334 of the active circuit structure 33 may only be disposed within the circuit region 33a, and may not extend to the non-circuit region 33b.

In some embodiments, the first bumps 51e may have a consistent maximum width W₅₁ₑ. The second bumps 52e may have a consistent maximum width W₅₂ₑ. The width W₅₂ₑ of the second bump 52e may be less than the width W₅₁ₑ of the first bump 51e. A pitch P₈ may be a distance between the centers of two adjacent first bumps 51e. The pitch P₈ of the first bumps 51e may be consistent. A pitch P₉ may be a distance between the centers of two adjacent second bumps 52e. The pitch P₈ may different form the pitch P₉. For example, the pitch P₈ may be less than the pitch P₉. Therefore, a distribution density of the first bumps 51e may be different from a distribution density of the second bumps 52e. For example, the distribution density of the first bumps 51e may be greater than the distribution density of the second bumps 52e. A gap or spacing between the first bumps 51e may be different from a gap or spacing between the second bumps 52e. For example, the gap or spacing between the first bumps 51e may be less than the gap or spacing between the second bumps 52e.

In some embodiments, the first connecting elements 4e may correspond to the first bumps 51e of the electronic device 3e. The structure of each of the first connecting elements 4e may be the same as or similar to the structure of each of the first connecting elements 4 of FIG. 4 and FIG. 5. In some embodiments, the first bumps 51e may connect to the first connecting elements 4e respectively through the first reflowable materials 55.

The first connecting element 4e may have a consistent maximum width W₄. A width of one of the first connecting elements 4e may be different from a width of one of the third connecting elements 29. The maximum width W₂₉ of the third connecting element 29 may be greater than the maximum width We of the first connecting element 4e. A pitch P₁₀ may be a distance between the centers of two adjacent first connecting elements 4e. The pitch P₁₀ of the first connecting elements 4 may be consistent. In some embodiments, the pitch P₁₀ of the first connecting elements 4 may be the same as the pitch P₈ of the first bumps 51e. Thus, a distribution density of the first connecting elements 4e may be the same as the distribution density of the first bumps 51e.

As shown in FIG. 13, a width W₅₅ of the first solder 55 may be different from a width W₅₆ of the second solder 56. The width W₅₆ of the second solder 56 is less than the width W₅₅ of the first solder 55, and the second solder 56 is closer to the periphery edge 296 of the carrier 2e than the first solder 55 is. In addition, the second solder 56 may extend laterally beyond an inner edge 274 of the carrier 2e (e.g., a lead frame). The inner edge 274 may face the first connecting element 4 (e.g., the terminal). That is, an edge 565 or lateral surface of the second solder 56 may extend beyond the inner edge 274. The inner edge 274 may be spaced apart from the first connecting element 4 (e.g., the terminal).

The circuit region 33a of the electronic device 3e may correspond to the first region 11 (i.e., the center region 11) of FIG. 6. The non-circuit region 33b of the electronic device 3e may correspond to the second region 12 (i.e., the intermediate region 12) of FIG. 6. The region of the package structure 1e surrounding the non-circuit region 33b may correspond to the third region 13 (i.e., the periphery region 13). The electronic device 3e may be disposed in the center region 11 and the intermediate region 12. The redistribution structure 8 may be disposed under the electronic device 3e. The carrier 2e may be disposed under the redistribution structure 8. At least one first pad 51e (e.g., a plurality of first pads 51e) may be disposed at a contact area between the redistribution structure 8 and the carrier 2e, and may be located in the center region 11. At least one second pad 52e (e.g., a plurality of second pads 52e) may be disposed at the contact area between the redistribution structure 8 and the carrier 2e, and may be located in the intermediate region 12. The width W₅₁ₑ of the first pad 51e may be different from the width W₅₂ₑ of the second pad 52e. For example, the width W₅₁ₑ of the first pad 51e may greater than the width W₅₂ₑ of the second pad 52e. The first pad 51e may be configured to transmit noise current. The second pad 52e may be configured to transmit signals. The pitch P₅ of two adjacent ones of the first pads 51e may be less than the pitch P₉ of two adjacent ones of the second pads 52e.

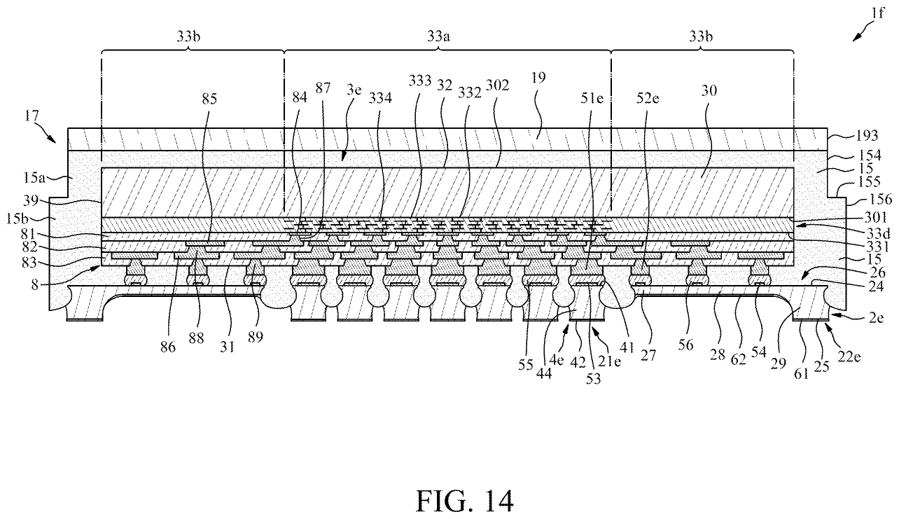

FIG. 14 illustrates a cross-sectional view of a package structure 1f according to some embodiments of the present disclosure. The package structure 1f of FIG. 14 is similar to the package structure 1e of FIG. 12, and the differences therebetween are described as follows.

The package structure 1f of FIG. 14 may further include a heat sink 19 (or a heat spreader) configured to dissipate the heat generated by the electronic device 3e. The heat sink 19 may be attached to the encapsulant 15 directly. The singulation process of the electronic device 3e may include a half-cut stage. Thus, a width of an upper portion 15a of the encapsulant 15 may be less than a width of a lower portion 15b of the encapsulant 15. A lateral surface 154 of the upper portion 15a of the encapsulant 15 may be mis-aligned with a lateral surface 156 of the lower portion 15b of the encapsulant 15. The lateral surface 154 of the upper portion 15a of the encapsulant 15, the lateral surface 156 of the lower portion 15b of the encapsulant 15 and a top surface 155 of the lower portion 15b of the encapsulant 15 may collectively define an indentation 17. A lateral surface 193 of the heat sink 19 may be aligned with the lateral surface 154 of the upper portion 15a of the encapsulant 15.

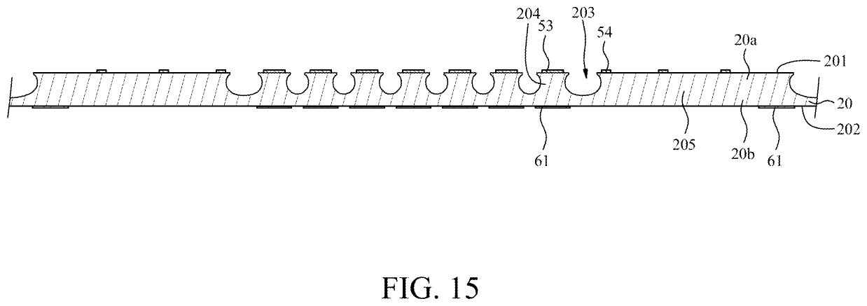

FIG. 15 through FIG. 19 illustrate a method for manufacturing a package structure according to some embodiments of the present disclosure. In some embodiments, the method is for manufacturing the package structure 1e shown in FIG. 12.

Referring to FIG. 15, a base material 20 may be provided. The base material 20 has a top surface 201 and a bottom surface 202 opposite to the top surface 201. Then, a plurality of first pads 53 and a plurality of second pads 54 may be formed on the top surface 201 of the base material 20. A plurality of conductive layers 61 may be formed on the bottom surface 202 of the base material 20. A portion of the conductive layers 61 may correspond to the first pads 53. Then, an etching process may be performed on the top surface 201 of the base material 20 so as to remove a portion of an upper portion 20a of the base material 20 and form a plurality of protrusions 204 and a recess portion 203 surrounding the protrusions 204. The protrusions 204 may protrude from a lower portion 20b of the base material 20. In addition, a remaining portion 205 (e.g., an unetched portion) may surround the protrusions 204 and the recess portion 203. The protrusions 204 may correspond to the first pads 53. The second pads 54 may be disposed on the remaining portion 205.

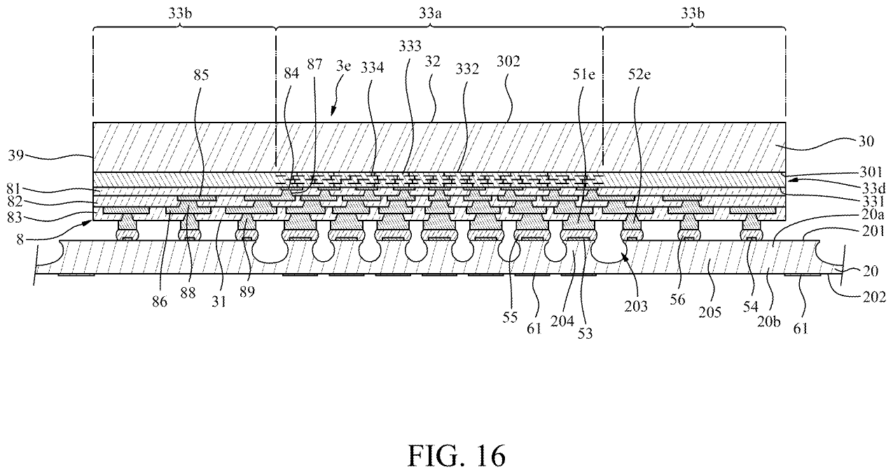

Referring to FIG. 16, an electronic device 3e may be attached to the base material 20 by, for example, flip-chip bonding. The electronic device 3e of FIG. 16 may be the same as the electronic device 3e of FIG. 12. The first bumps 51e of the electronic device 3e may be attached to the protrusions 204 through a plurality of first reflowable materials 55. The first reflowable materials 55 may cover the first pads 53. The second bumps 52e of the electronic device 3e may be attached to the remaining portion 205 through a plurality of second reflowable materials 56. The second reflowable materials 56 may cover the second pads 54.

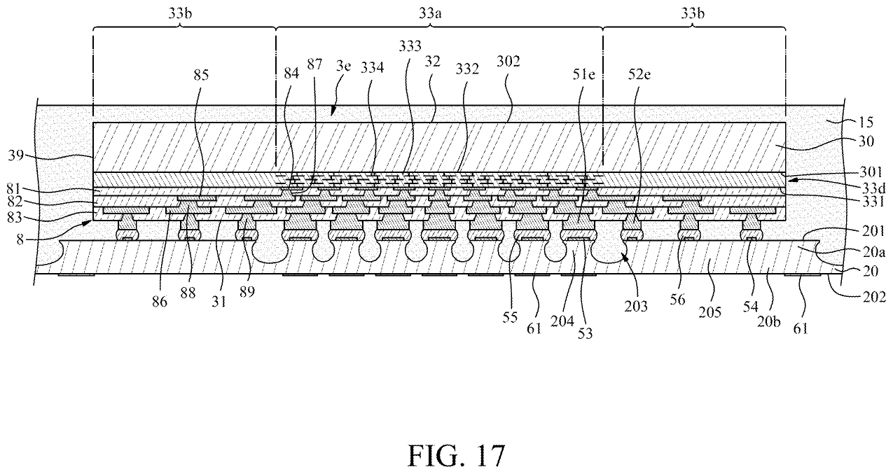

Referring to FIG. 17, an encapsulant 15 may be formed or disposed on the top surface 201 of the base material 20 to encapsulate the electronic device 3e. A portion of the encapsulant 15 may extend into the recess portion 203 to cover and contact the protrusions 204.

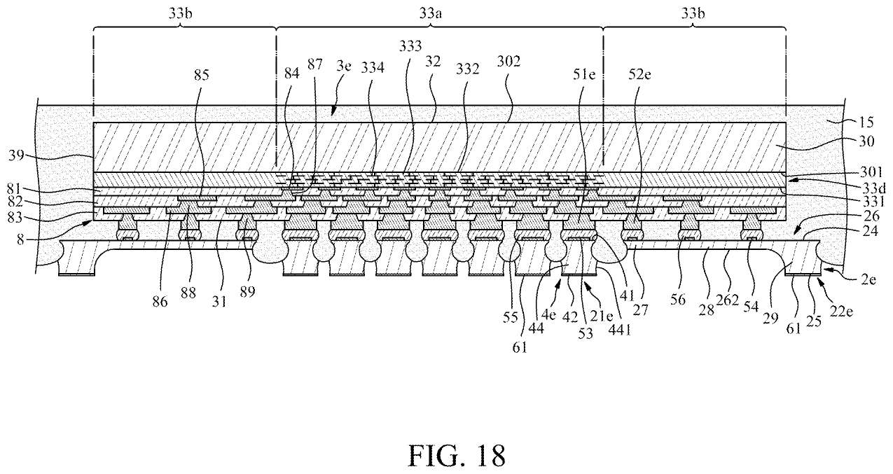

Referring to FIG. 18, an etching process may be performed on the bottom surface 202 of the base material 20 so as to remove a portion of the lower portion 20b of the base material 20 and form a plurality of first connecting elements 4e and a plurality of leads 26. The first connecting elements 4e may be formed from the protrusions 204. The leads 26 may be formed from the remaining portion 205. Meanwhile, the base material 20 may be manufactured to become a carrier 2e of FIG. 12. As shown in FIG. 18, the lateral surface 441 of the lower portion 44 of the first connecting element 4e and a bottom surface 262 (including the bottom surface 272 of the second connecting element 27 (FIG. 13), the bottom surface 282 of the trace 28 (FIG. 13), the second lateral surface 294 of the third connecting element 29 (FIG. 13) and the third lateral surface 295 of the third connecting element 29 (FIG. 13)) of the lead 26 may be exposed by the encapsulant 15.

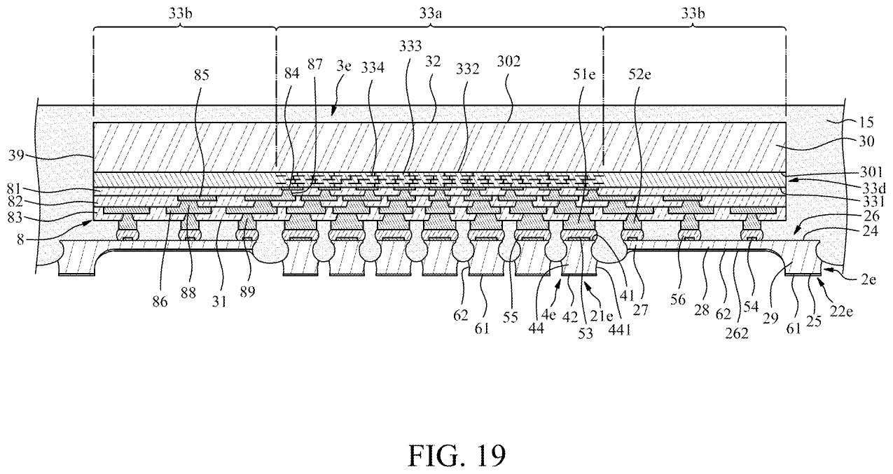

Referring to FIG. 19, a protection layer 62 (e.g., a solder resist layer) may be formed or disposed on the lower lateral surface 441 of the lower portion 44 of the first connecting element 4e and the bottom surface 262 (including the bottom surface 272 of the second connecting element 27 (FIG. 13), the bottom surface 282 of the trace 28 (FIG. 13), the second lateral surface 294 of the third connecting element 29 (FIG. 13) and the third lateral surface 295 of the third connecting element 29 (FIG. 13)) of the lead 26.

Then, a singulation process may be conducted so as to obtain a plurality of package structures 1e shown in FIG. 12.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a lead frame;
an electronic device disposed adjacent to the lead frame; and
a level-maintaining structure disposed between the electronic device and the lead frame, and configured to prevent the electronic device from tilting with respect to the lead frame, wherein the electronic device includes at least one via protruding from a bottom surface of the electronic device.

2. The package structure of claim 1, wherein the at least one via includes a plurality of vias having inconsistent gaps between adjacent vias and configured to transmit noise current.

3. The package structure of claim 2, wherein the plurality of vias includes a first via having a first width, a second via having a second width, and a third via having a third width, wherein the first width, the second width and the third width are different from each other.

4. The package structure of claim 2, wherein the electronic device includes a high-density region and a low-density region, a distribution density of the plurality of vias in the high-density region is greater than a distribution density of the plurality of vias in the low-density region, wherein the level-maintaining structure is disposed under the low-density region.

5. The package structure of claim 1, wherein the at least one via includes a dummy via, and the level-maintaining structure includes a protrusion portion of the dummy via protruding from the bottom surface of the electronic device.

6. The package structure of claim 1, wherein the level-maintaining structure is disposed under the electronic device, and includes a solder material, wherein the package structure further comprises a dummy pad disposed between the solder material and the electronic device, and configured to adjust a thickness of the solder material.

7. The package structure of claim 1, wherein the at least one via includes a plurality of vias having a plurality of bottom surfaces substantially level with each other.

8. The package structure of claim 7, further comprising a bonding layer disposed between the electronic device and the lead frame, wherein a portion of the at least one via and a dummy pad are disposed in the bonding layer.

9. A package structure, comprising:
a terminal;
an upper pad adjacent to a top surface of the terminal; and
a first solder disposed over the upper pad, and free from contacting a lateral surface of the upper pad, wherein the upper pad is configured to prevent the first solder from lateral bleeding.

10. The package structure of claim 9, further comprising a second solder contacting a top surface of a lead frame.

11. The package structure of claim 10, wherein the second solder covers a second upper pad, and is asymmetric with respect to a center axis of the second upper pad.

12. The package structure of claim 9, further comprising a second solder extending laterally beyond an inner edge of a lead frame facing the terminal.

13. The package structure of claim 12, wherein a width of the first solder is different from a width of the second solder.

14. The package structure of claim 13, wherein the width of the second solder is greater than the width of the first solder, and the second solder is closer to a periphery edge of the lead frame than the first solder is.

15. The package structure of claim 14, wherein a maximum thickness of the first solder is different from a maximum thickness of the second solder in a cross-sectional view.

16. The package structure of claim 9, further comprising:
a lead tapering, and having a contact surface and a lower surface outside the contact surface, wherein the lower surface extends from a thicker end to a thinner end; and
a solder mask disposed on the lower surface and exposing a portion of the lower surface.

17. The package structure of claim 16, wherein the solder mask partially covers an encapsulant.

18. The package structure of claim 17, wherein the solder mask tapers toward the contact surface.

19. A package structure including a center region, a periphery region and an intermediate region therebetween from a top view, and comprising:
an electronic device disposed in the center region and the intermediate region;
a redistribution structure disposed under the electronic device;
a carrier disposed under the redistribution structure;
at least one first pad disposed at a contact area between the redistribution structure and the carrier and in the center region; and
at least one second pad disposed at the contact area between the redistribution structure and the carrier and in the intermediate region, wherein a width of the at least one first pad is different from a width of the at least one second pad, the at least one first pad is configured to transmit noise current, and the at least one second pad is configured to transmit signals.

20. The package structure of claim 19, wherein the at least one first pad includes a plurality of first pads, the at least one second pad includes a plurality of second pads, wherein a pitch of two adjacent ones of the plurality of first pads is less than a pitch of two adjacent ones of the plurality of second pads.
